(19) United States
(12) Patent Application Publication
(10) Pub. No.: US 2009/0295492 A1
(43) Pub. Date: Dec. 3, 2009

(54) BIASED VARACTOR NETWORKS AND METHODS TO USE THE SAME

(76) Inventor: Salvatore Finocchiaro, Dallas, TX (US)

Correspondence Address: TEXAS INSTRUMENTS INCORPORATED, P O BOX 655474, M/S 3999, DALLAS, TX, 75265, US

(21) Appl. No.: 12/127,478

(22) Filed: May 27, 2008

(51) Int. Cl. H03B 5/18; H03H 5/12

(52) U.S. Cl. 331/117 R; 334/15

(57) ABSTRACT

Example biased varactor networks and methods to use the same are disclosed. A disclosed example apparatus includes a bias voltage generator to generate a first bias voltage and a second bias voltage, the second bias voltage selected to be different from the first bias voltage, and a varactor network comprising first and second varactors connected to receive a control voltage, the control voltage configurable to control a capacitance of the varactor network, the capacitance of the varactor network comprising a first capacitance of the first varactor determined by a first difference between the control voltage and the first bias voltage and a second capacitance of the second varactor determined by a second difference between the control voltage and the second bias voltage.

### FIELD OF THE DISCLOSURE

This disclosure relates generally to varactors, and, more particularly, to biased varactor networks and methods to use the same.

### BACKGROUND

A varactor is a device, circuit or component having a capacitance that varies with a control or tuning voltage. A varactor may be used, for example, in a voltage-controlled oscillator (VCO) circuit, where a tuning voltage is used to control the capacitance of the varactor and, thus, the oscillation frequency of the VCO circuit. A varactor may be constructed, for example, using a reversed-biased p-n junction, or a p-well or n-well MOS capacitor, or any combination thereof.

### SUMMARY

Example biased varactor networks and methods to use the same are disclosed. In some examples, by biasing varactors of a varactor network at different voltages, the total or collective range of capacitance implemented by the varactor network is increased and more evenly distributed across a wider range of a tuning voltage used to control the varactor network. When such an example biased varactor network is used in a voltage-controlled oscillator (VCO) circuit, the VCO circuit has a more linear gain providing, among other things, better or more constant performance, improved loop stability and/or reduced locking time for a closed loop system (e.g., a phase-locked loop) used to control the VCO circuit.

A disclosed example apparatus includes a bias voltage generator to generate a first bias voltage and a second bias voltage, the second bias voltage selected to be different from the first bias voltage, and a varactor network comprising first and second varactors connected to receive a control voltage, the control voltage configurable to control a capacitance of the varactor network, the capacitance of the varactor network comprising a first capacitance of the first varactor determined by a first difference between the control voltage and the first bias voltage and a second capacitance of the second varactor determined by a second difference between the control voltage and the second bias voltage.

A disclosed example varactor circuit includes a first varactor having a first terminal to receive a tuning signal and a second terminal to receive a first bias signal, and a second varactor having a third terminal to receive the tuning signal, and a fourth terminal to receive a second bias signal, the second bias signal selected to be different from the first bias signal to control a first capacitance of the first varactor relative to a second capacitance of the second varactor.

A disclosed example VCO circuit includes a first inductor electrically coupled to a first terminal of the varactor network at a first node, wherein a first output signal of the VCO circuit is generated at the first node, a second inductor electrically coupled to a second terminal of the varactor network at a second node, wherein a second output signal of the VCO circuit is generated at the second node, a first transistor having a first source terminal electrically coupled to the first node and a first gate terminal electrically coupled to the first node, and a second transistor having a second source terminal electrically coupled to the second node and a second gate terminal electrically coupled to the second node.

### BRIEF DESCRIPTION OF THE DRAWINGS

FIG. 1 is a schematic diagram of an example prior-art varactor network.

FIG. 2 is a schematic diagram of an example varactor circuit constructed in accordance with the teachings of the disclosure.

FIG. 3A is a schematic diagram of an example manner of implementing the example biased varactor network of FIG. 2.

FIG. 3B is a schematic diagram of an example manner of implementing the example bias voltage generator of FIG. 2

FIG. 4 is a schematic diagram of an example voltage-controlled oscillator (VCO) circuit constructed using the example varactor circuit of FIG. 2.

FIGS. 5 and 6 illustrate comparisons between the VCO circuit of FIG. 4 implementing the prior-art varactor network of FIG. 1 and the example varactor circuit of FIGS. 2, 3A and 3B.

FIG. 7 is a schematic diagram of an example voltage-controlled oscillator (VCO) circuit constructed using the example varactor circuit of FIG. 2.

FIGS. 8A and 8B are schematic diagrams of example varactor circuits used to simulate benefits resulting from use of a biased varactor network.

FIGS. 9A and 9B illustrate example simulation results for the example varactor circuits of FIGS. 8A and 8B.

Wherever possible, the same reference numbers will be used throughout the drawing(s) and accompanying written description to refer to the same or like parts.

### DETAILED DESCRIPTION

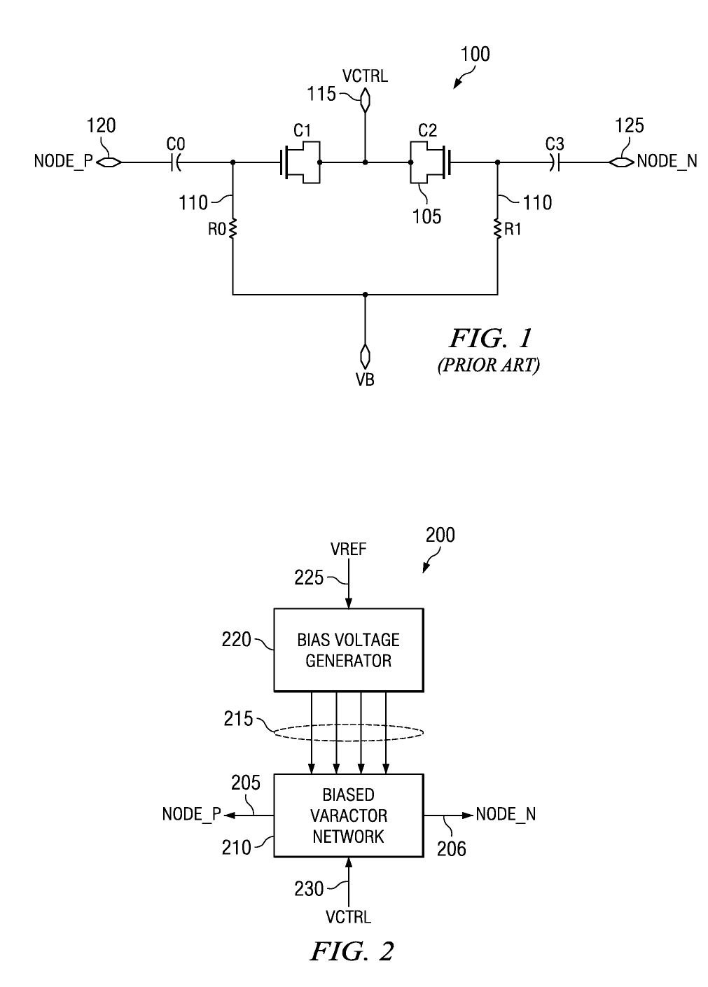

FIG. 1 is a schematic diagram of an example varactor network 100. The example varactor network 100 of FIG. 1 includes a plurality of varactors and/or varactor cells, one of which is designated at reference numeral 105. A varactor is a device, circuit or component having a capacitance that varies with a control or tuning voltage. Each of the example varactors 105 of FIG. 1 is biased with a bias voltage 110, and the capacitance of each of the varactors 105 is controlled by a tuning voltage 115. In the illustrated example of FIG. 1, the varactors 105 are arranged to collectively implement a variable capacitance between two nodes 120 and 125.

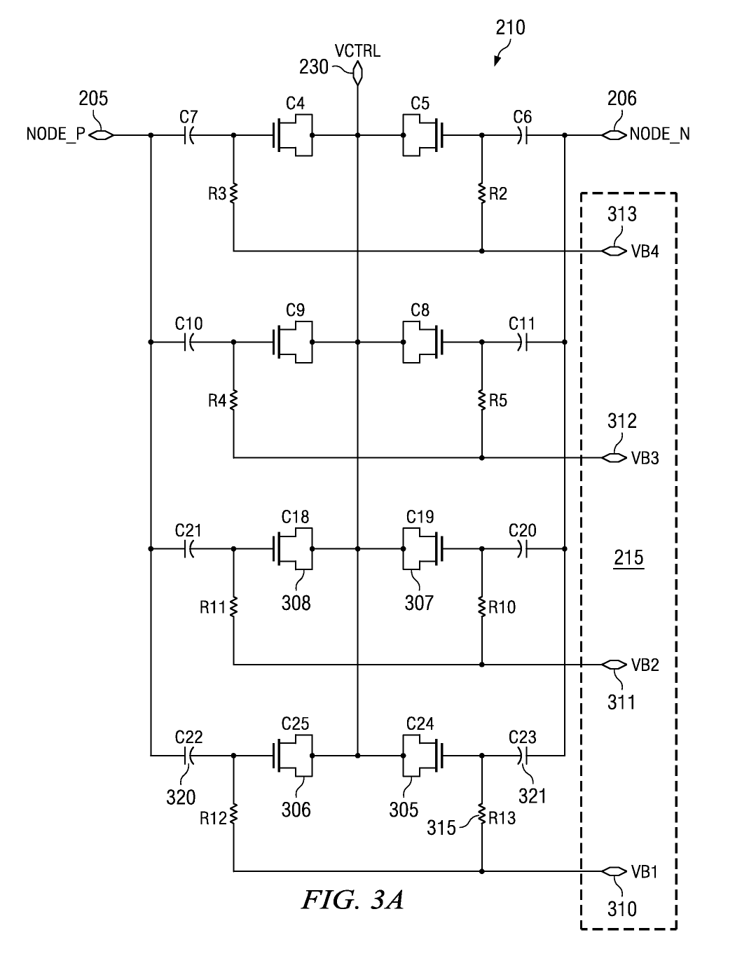

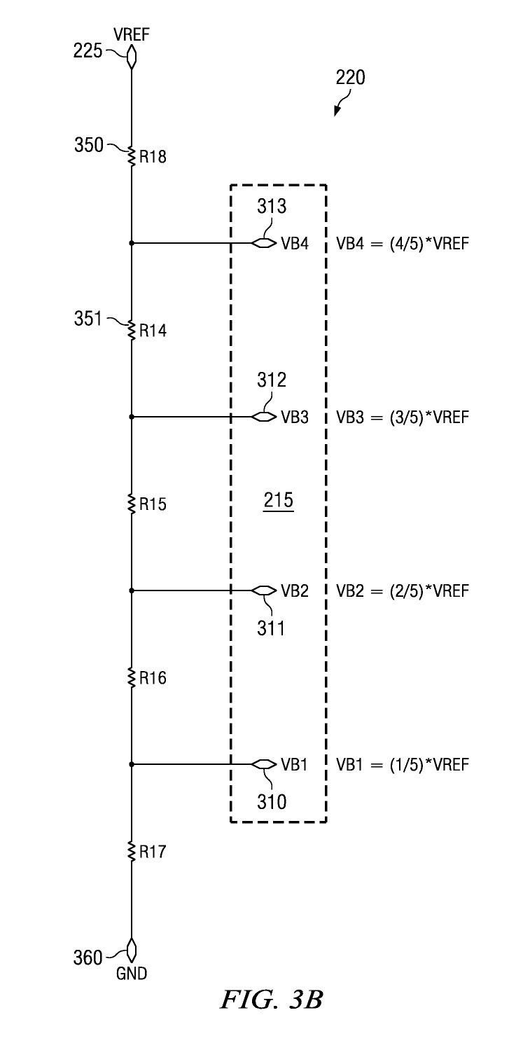

FIG. 2 is a schematic diagram of an example varactor circuit 200 constructed in accordance with the teachings of the disclosure. To implement a variable capacitance between two nodes 205 and 206, the example varactor circuit 200 of FIG. 2 includes a biased varactor network 210. To generate bias voltages 215 having different amplitudes or voltages, the example varactor circuit 200 of FIG. 2 includes a bias voltage generator 220. The example bias voltage generator 220 of FIG. 2 generates the bias voltages 215 from a reference voltage 225 using, for example, a voltage divider circuit including series resistors. An example manner of implementing the example bias voltage generator 220 is described below in connection with FIG. 3B.

As described below in connection with FIG. 3A, the example bias voltages 215 of FIG. 2 are used to bias varactors or varactor cells of the example biased varactor network 210 at different voltages so that to least some varactors have different capacitances for a particular tuning or control voltage 230. Such a biased varactor configuration increases the total or collective range of capacitance implemented by the biased varactor network 210, and more evenly distributes the range of the capacitance across a wider range of the control voltage 230.

During an example operation of the example varactor circuit 200 of FIG. 2, the bias voltages 215 are held substantially constant (i.e., are substantially direct current (DC) signals), while the control voltage 230 is adjusted to control or configure the capacitance of the biased varactor network 210. For example, if the varactor circuit 200 is used in a voltage-controlled oscillator (VCO) circuit, the control voltage 230 may be controlled to control, tune and/or adjust the frequency of a signal generated by the VCO circuit. While the bias voltages 215 are held substantially constant during example operations of the varactor circuit 200 described herein, they need not be held constant.

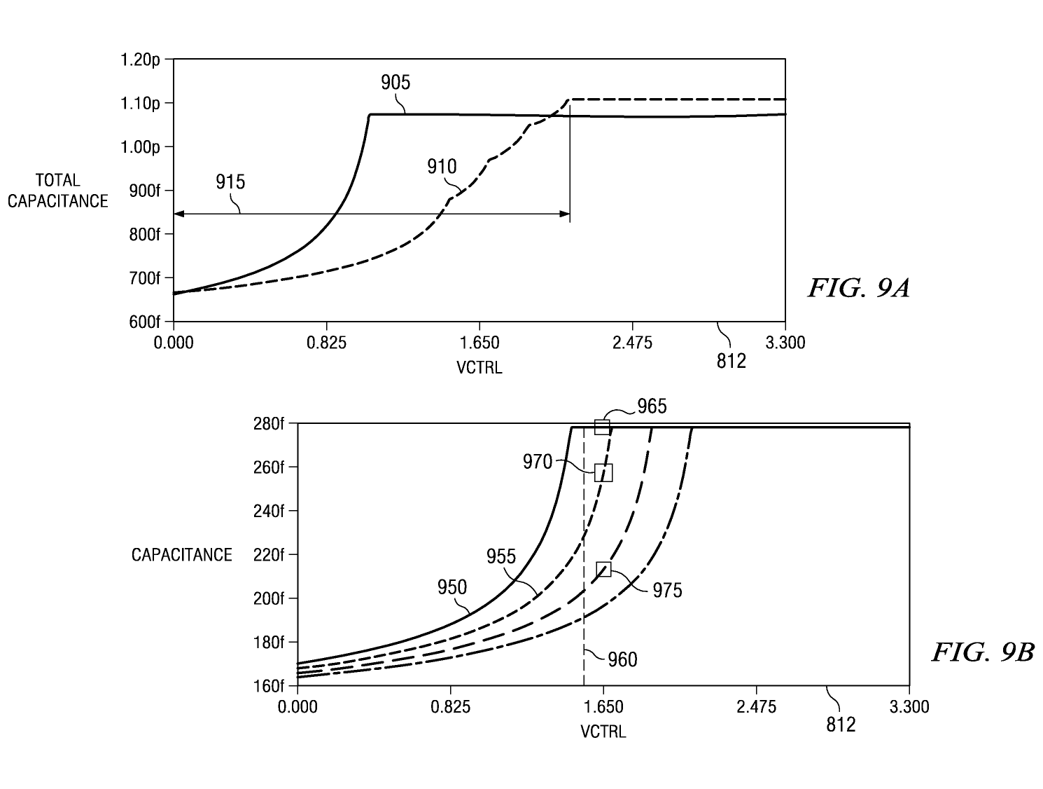

FIG. 3A is a schematic illustration of an example manner of implementing the example biased varactor network 210 of FIG. 2. The example biased varactor network 210 of FIG. 3A includes a plurality of varactors and/or varactor cells, four of which are designated at reference numerals 305-308. The example varactors 305-308 of FIG. 3 each have a capacitance of approximately 250 femtoFarads (fF) at a bias voltage of 0 volts (V) and a maximum tuning voltage (e.g., 3.3 V), and the varactor network 210 has a collective capacitance of approximately 1 picoFarads (pF) at a bias voltage of 0 V and the maximum tuning voltage. During operation, to facilitate tuning, the capacitance of each of the example varactors 305-308 of FIG. 3 is controlled or adjusted by the tuning or control voltage 230. In contrast to the example varactor network 100 of FIG. 1, the example varactors 305-308 of FIG. 3A are biased with different bias voltages 215, 310-313. In the illustrated example of FIG. 3A, a first pair of varactors 305 and 306 is biased with a first bias voltage 310, and a second pair of varactors 307 and 308 is biased with a second bias voltage 311. The example bias voltages 310-313 of FIG. 3A are selected to have progressively increasing voltages. Thus, for a particular control voltage 230 (e.g., 0 V), the varactors 305-308 have different capacitances depending on the difference between the control voltage 230 and their respective bias voltage 310-313. For example, for a particular control voltage 230, the capacitance of the pair of varactors 305 and 306 will be less than the capacitance of the pair of varactors 307 and 308. That is, the different bias voltages 310 and 311 offset the capacitance versus tuning voltage curve of the pair of varactors 307 and 308 relative to the pair of varactors 305 and 306, as illustrated below in connection in FIG. 9B. Example bias voltages 310, 311, 312 and 313 are 300 millivolts (mV), 600 mV, 900 mV and 1.2 V, respectively. In general, the number and voltages of the bias voltages 310-313 are application specific. For example, the number of bias voltages 310-313 may be selected to control or adjust the linearity of the collective capacitance versus control voltage response of the varactor network 210 (e.g., the example curve 910 of FIG. 9B). In some examples, the voltages of the bias voltages 215 are selected to implement a VCO gain response centered near a mid-point of the range of the control voltage 230 (e.g., VDD/2) and extending from a control voltage 230 of 0 V to a maximum voltage of the control voltage 230 (e.g., VDD).

The example varactors 305-308 of FIG. 3A may be any type of varactors constructed using, for example, a p-well or n-well metal-oxide semiconductor (MOS) capacitor or a p-n junction. When MOS capacitors are used to construct the example varactors 305-308, the bias voltages 310-313 are applied to corresponding gates of the MOS capacitors. When p-n junctions are used to construct the example varactors 305-308, the bias voltages 310-313 are used as reverse-bias voltages for the p-n junctions.

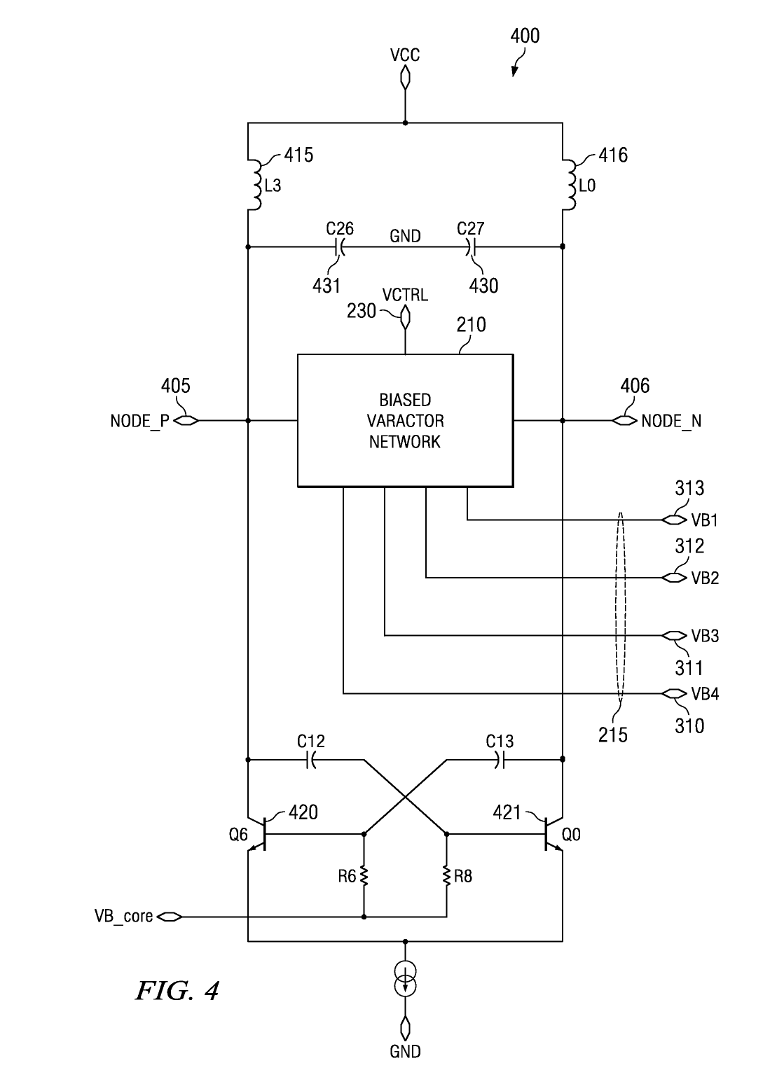

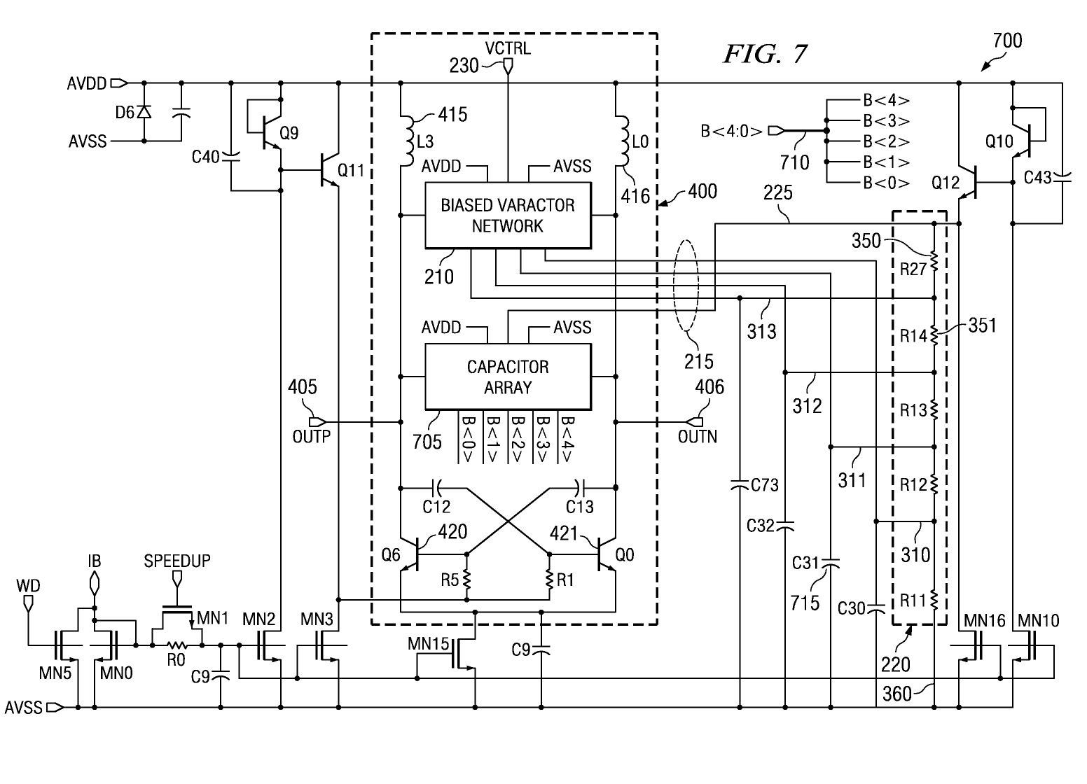

Biasing the example varactors 305-308 of FIG. 3A at different bias voltages 310-313 advantageously increases the total or collective range of capacitance implemented by the biased varactor network 210, and more evenly distributes the range of the capacitance across a wider range of the control voltage 230. As such, the capacitance versus tuning voltage curve of the biased varactor network 210 is more linear than a conventional varactor circuit. When, for example, the example biased varactor network 210 is used to implement capacitance for an oscillator of a VCO circuit (e.g., the example VCO circuit 400 of FIG. 4 and/or the example VCO circuit 700 of FIG. 7), the gain of the VCO circuit is flatter or more linear across the range of the control voltage 230. A flatter or more linear gain provides, among other things, better or more constant performance, improved loop stability and/or reduced locking time for a closed loop system (e.g., a phase-locked loop) used to control the VCO circuit. A VCO circuit implementing the example varactor network 210 may be used for or in any number and/or type(s) of applications, which benefit from substantially linear tuning responses, such as, for example, wide-band phase locked loops for radio frequency (RF) applications.

To couple the bias voltages 310-313 to the varactors 305-308, the example varactor network 210 of FIG. 3A includes resistors for respective ones of the varactors 305-308, one of which is designated at reference numeral 315. To block DC signals, the example varactor network 210 of FIG. 3A includes capacitors for respective ones of the varactors 305-308, two of which are designated at reference numerals 320 and 321. The example capacitors 320-321 of FIG. 3A block DC signals or currents from appearing on the outputs 205 and 206.

FIG. 3B is a schematic illustration of an example manner of implementing the example bias voltage generator 220 of FIG. 2. To generate the bias voltages 215, the example bias voltage generator 220 of FIG. 3B includes a set of resistors configured in a series topology, two of which are designated at reference numerals 350 and 351, that progressively divide the reference voltage 225 to generate the example bias voltages 310-313. While the example bias voltage generator 220 of FIG. 3B implements a set of series resistors 350 and 351 to generate the bias voltages 310-313, any number and/or type(s) of additional or alternative components or circuits could be used to generate the bias voltages 310-313. For example, any combination and/or topology of capacitors, capacitance ratios, voltage regulators, voltage generators, diodes, MOS devices and/or resistors.

The example resistors 350-351 of FIG. 3B are selected so that the bias voltages 310-313 of FIG. 3B equally divide the voltage range defined by the reference voltage 225 and a second reference voltage 360 (e.g., a ground signal). In particular, the example resistors 350-351 of FIG. 3B are selected to generate bias voltages 310-313 of (n/(N+1))*VREF, where n is selected from n=1, . . . N, N is the number of bias voltages 310-313, and VREF is the value of the reference voltage 225.

An example reference voltage 225 is generated using two diodes such that the example reference voltage 225 as a voltage of VDD minus the collective voltage drop of the two diodes. However, the reference voltage 225 could be generated by any number and/or type(s) of alternative or additional components and/or circuits and could be generated to have any voltage.

FIG. 4 is a schematic diagram of an example VCO circuit 400 that includes the example varactor circuit 200 of FIG. 2. To generate output signals 405 and 406, the example VCO circuit 400 of FIG. 4 includes the example varactor network 210, a pair of inductors 415 and 416, and cross-coupled transistors 420 and 421. The varactor network 210, the inductors 415 and 416 and the cross-coupled transistors 420 and 421 are configured in an LC-based oscillator topology. The example varactor network 210 and two capacitors 430 and 431 implement the capacitance for the example VCO circuit 400. The example varactor network 210 implements a variable capacitance in response to the control voltage 230 to allow the operating frequency of the VCO circuit 400 to be controlled, tuned and/or configured. The example bias voltages 310-313 of FIG. 4 may be generated by, for example, the example bias voltage generator 220 of FIG. 3B.

While the example VCO circuit 400 of FIG. 4 implements an LC-based oscillator using NPN transistors, the example varactor network 210 can be used to implement variable capacitance for any application (e.g., RF) utilizing a resonant tank circuit (LC) with tunable capability including, but not limited to, VCO circuits, voltage-controlled crystal oscillators, and/or tunable RF filters. Moreover, the example varactor circuit 200 of FIG. 2 may be used to implement variable capacitance for any number and/or type(s) of other circuits and/or applications. Further, while the example varactor network 210 of FIGS. 2 and 3A and the example VCO circuits 400 and 700 of FIGS. 4 and 7 are implemented using differential signals, singled-ended biased varactor networks and/or circuits using single-ended biased varactors may be implemented based on the examples disclosed herein.

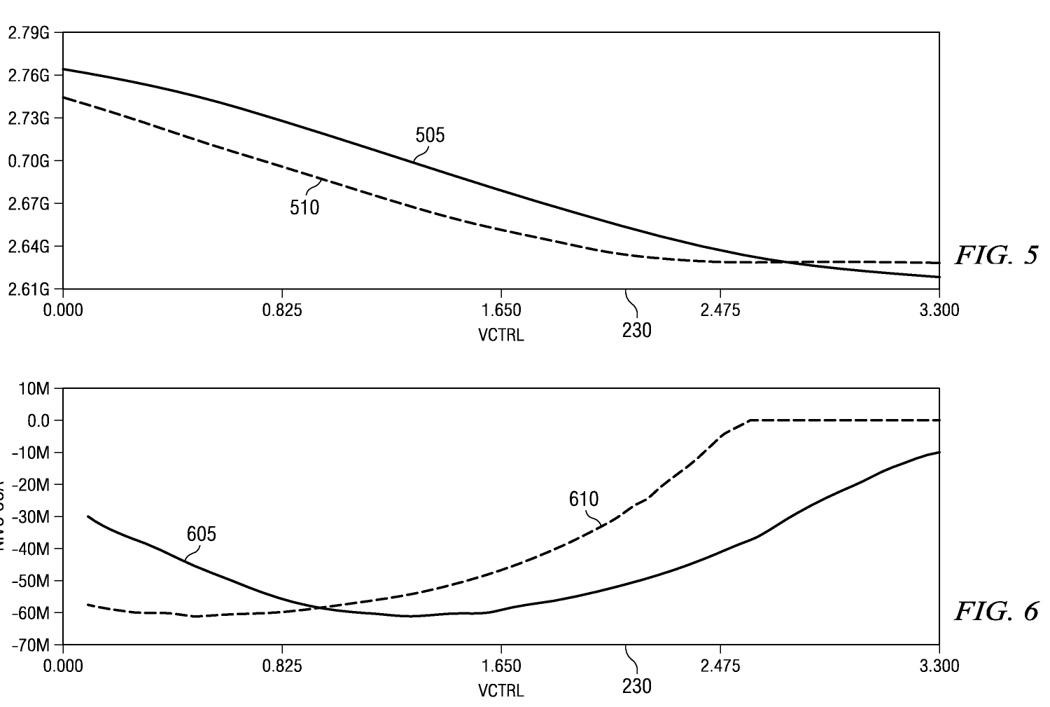

FIGS. 5 and 6 are graphs illustrating example performance characteristics of the example VCO circuit 400 of FIG. 4. FIG. 5 shows a VCO output frequency versus control voltage curve 505 for the example VCO circuit 400 of FIG. 4. Also shown in FIG. 5 is a second curve 510 representing the VCO output frequency versus control voltage response of the VCO circuit 400 were the example biased varactor network 210 of FIG. 4 replaced with the example varactor network 100 of FIG. 1. As shown in FIG. 5, by implementing the example bias varactor network 210 rather than the example varactor network 110, the example VCO circuit 400 advantageously has a wider tuning range (approximately 145 MHz versus 115 MHz) and a more linear response.

FIG. 6 shows a VCO gain versus control voltage curve 605 for the example VCO circuit 400 of FIG. 4. Also shown in FIG. 6 is a second curve 610 representing the VCO gain versus control voltage response of the VCO circuit 400 were the example biased varactor network 210 of FIG. 4 replaced with the example varactor network 100 of FIG. 1. As shown in FIG. 6, by implementing the example bias varactor network 210 rather than the example varactor network 110, the example VCO circuit 400 advantageously has a VCO gain response that is flatter and that is approximately centered at the mid-point of the control voltage 230.

FIG. 7 is a schematic diagram of another example VCO circuit 700 that includes the example varactor network 210 and the example bias voltage generator 220 of FIGS. 2, 3A and/or 3B. To extend the range of tuning frequencies implementable by the example VCO circuit 700 of FIG. 7, the VCO circuit 700 includes a capacitor array 705. The example capacitor array 705 of FIG. 7 replaces the example capacitors 430 and 431 of FIG. 4. Based on control inputs 710, the example capacitor array 705 of FIG. 7 implements one of a set of capacitances. The capacitance of the capacitor array 705 together with the capacitance of the example biased varactor network 210 controls the oscillation frequency of the VCO circuit 700. By controlling the inputs 710 and the control voltage 230, the capacitor array 705 and the varactor network 210 can collectively implement a wide range of capacitance values. For example, a first combination of inputs 710 configures the VCO circuit 700 to be tunable over a first set of frequencies by adjusting the capacitance of the biased varactor network 210 with the control voltage 230, and a second combination of inputs 710 configures the VCO circuit 700 to be tunable over a second range of frequencies by adjusting the capacitance of the biased varactor network 210 with the control voltage 230. In some examples, the first and second ranges of frequencies values may overlap.

To improve the performance of the example oscillator 400 of FIG. 7, the example bias voltages 310-313 are coupled to respective capacitors, one of which is designated a reference numeral 715. The example capacitors 715 of FIG. 7 limit or reduce noise present on the bias voltages 310-313 from being introduced into the oscillator 400. Were such undesirable noise introduced into the oscillator 400, the performance of the oscillator 400 may be compromised.

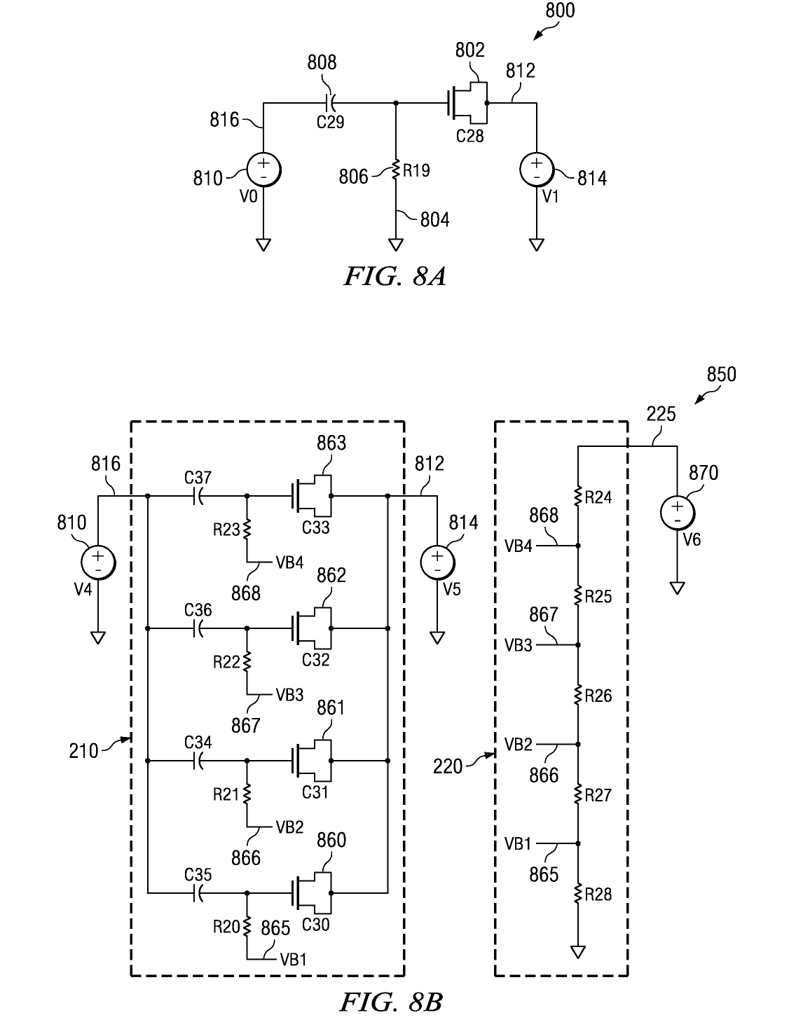

FIGS. 8A and 8B are schematic diagrams of example circuits used to simulate the benefits resulting from splitting a single varactor into a set of smaller varactors, which are biased at different bias voltages. The example varactor network 800 of FIG. 8A includes a single p-well MOS varactor 802 of size 100×(5/0.42) biased by a ground signal 804 at voltage of 0 V. The ground signal 804 is coupled to the varactor 802 via a resistor 806. A capacitor 808 blocks a DC current or signal from flowing through the varactor 802. A voltage source 810 is used to bias the varactor circuit 800 to replicate typical circuit conditions were the example varactor 802 to be used in a VCO circuit, such as the example VCO circuits 400 and/or 700. A control voltage 812 for the varactor 802 is provided by a configurable voltage source 814. The capacitance of the varactor circuit 800 is measured at a node 816.

The example varactor circuit 850 of FIG. 8B is configured similarly to the example varactor circuit 800 of FIG. 8A, however, the single varactor 802 of FIG. 8A is split into four p-well MOS varactors 860-863 of size 25(5/0.42), which are biased at respective bias voltages 865-868 of 300 mV, 600 mV, 900 mV and 1.2 V by the example bias voltage generator 220. The example reference voltage 225 of FIG. 8B is generated by a voltage source 870. Similar to the example varactor circuit of FIG. 8A, the bias voltages 865-868 are coupled to their respective varactor 860-863 via a resistor, and each of the varactors 860-863 has an associated capacitor to block DC signals or currents.

FIG. 9A is a graph illustrating example total or collective capacitance versus tuning voltage response curves 905 and 910 for the example varactor circuit 800 of FIG. 8A and the example varactor circuit 850 of FIG. 8B, respectively. As shown in FIG. 9A, the capacitance versus tuning voltage response 910 for the varactor network 850 of FIG. 8B is substantially more linear than the response 905 for the varactor network 800 of FIG. 8A. Moreover, the total capacitance of the varactor network 850 of FIG. 8B is controllable across a wider range 915 of the control voltage 812, as shown in FIG. 9A.

FIG. 9B is a graph illustrating the capacitance of each of the example varactors 860-863 of FIG. 8B as function of the control voltage 812. Because the example varactors 860-863 of FIG. 8B are biased with progressively larger bias voltages 865-868, their capacitance versus control voltage curves are correspondingly offset, as shown in FIG. 9B. That is, the tuning voltage 812 necessary for a particular varactor 860-863 to have a particular capacitance depends on the bias voltage 865-868 of the varactor 860-863. In the example graph of FIG. 9B, a first curve 950 corresponding to the example varactor 860 is offset with respect to a second curve 955 corresponding to the example varactor 861. As shown in FIG. 9B, the capacitance versus control voltage curves of the individual varactors 860-863 are substantially non-linear. However, by offsetting the varactors 860-863 using different bias voltages 865-868, their combined total capacitance versus control voltage curve 910 becomes substantially more linear, as shown in FIG. 9A. As the control voltage 812 is increased the capacitance of the varactors 860-863 are, in sequence, increased. For example, for a particular control voltage 960, the varactor 860 has already reach maximum capacitance 965, the varactor 861 has reach a large, but not yet maximum, capacitance 970, and the varactor 862 reached a low capacitance 975, etc.

While example manners of implementing and using a biased varactor network are illustrated in FIGS. 2, 3A, 3B, 4, 7 and 8B, a biased varactor network may be implemented using any number and/or type(s) of alternative and/or additional logic, devices, components, circuits, modules, interfaces, etc. For example, while the example biased varactor circuits disclosed herein are constructed using p-well MOS capacitors, the example varactor biasing methods and apparatus disclosed herein can be used in connection with other types of varactors, such as n-well MOS based varactors. For example, to bias a n-well based varactor network the bias voltages 215 are distributed based on the supply voltage VDD rather than on the supply voltage VSS. Further, the logic, devices, components, circuits, modules, elements, interfaces, etc. illustrated in FIGS. 2, 3A, 3B, 4, 7 and/or 8B may be combined, divided, re-arranged, omitted, eliminated and/or implemented in any other way. Moreover, a biased varactor network and/or a device using the same may include additional logic, devices, components, circuits, interfaces and/or modules instead of, or in addition to those illustrated in FIGS. 2, 3A, 3B, 4, 7 and/or 8B.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. An apparatus comprising:
a bias voltage generator to generate a first bias voltage and a second bias voltage, the second bias voltage selected to be different from the first bias voltage; and
a varactor network comprising first and second varactors connected to receive a control voltage, the control voltage configurable to control a capacitance of the varactor network, the capacitance of the varactor network comprising a first capacitance of the first varactor determined by a first difference between the control voltage and the first bias voltage and a second capacitance of the second varactor determined by a second difference between the control voltage and the second bias voltage.

2. An apparatus as defined in claim 1, wherein the second bias voltage increases the first capacitance relative to the second capacitance.

3. An apparatus as defined in claim 1, wherein the varactor network further comprises third and fourth varactors, and the capacitance of the varactor network further comprises a third capacitance of the third varactor determined by a third difference between the control voltage and the first bias voltage and a fourth capacitance of the fourth varactor determined by a fourth difference between the control voltage and the second bias voltage.

4. A varactor network circuit comprising:
a first varactor having a first terminal to receive a tuning signal and a second terminal to receive a first bias signal; and
a second varactor having a third terminal to receive the tuning signal, and a fourth terminal to receive a second bias signal, the second bias signal selected to be different from the first bias signal to control a first capacitance of the first varactor relative to a second capacitance of the second varactor.

5. A varactor network circuit as defined in claim 4, further comprising:
a first capacitor having a fifth terminal electrically coupled to the second terminal and a sixth terminal electrically coupled to an output node; and
a second capacitor having a seventh terminal electrically coupled to the fourth terminal and an eight terminal electrically connected to the output node.

6. A varactor network circuit as defined in claim 4, further comprising:
a third varactor having a fifth terminal to receive the tuning signal and a sixth terminal to receive the first bias signal; and
a fourth varactor having a seventh terminal to receive the tuning signal and a eighth coupled to receive the second bias signal.

7. A varactor network circuit as defined in claim 6, wherein the first and second varactors are coupled at a first output node, and the third and fourth varactor are coupled at a second output node.

8. A varactor network circuit as defined in claim 4, wherein the first varactor comprises a metal-oxide semiconductor (MOS) capacitor, and the second terminal comprises a gate of the MOS capacitor.

9. A voltage-controlled oscillator (VCO) circuit comprising:
a bias voltage generator to generate a first bias voltage and a second bias voltage different from the first bias voltage; and
an oscillator comprising a varactor network, the varactor network to provide a capacitance and having first and second varactors connected to receive a tuning voltage, the tuning voltage configurable to control a capacitance of the varactor network, the capacitance of the varactor network comprising a first capacitance of the first varactor determined by a first difference between the tuning voltage and the first bias voltage and a second capacitance of the second varactor determined by a second difference between the tuning voltage and the second bias voltage, the second bias voltage selected to be different from the first bias voltage.

10. A VCO oscillator circuit as defined in claim 9, wherein the oscillator further comprises:
a first inductor electrically coupled to a first terminal of the varactor network at a first node, wherein a first output signal of the VCO circuit is generated at the first node;
a second inductor electrically coupled to a second terminal of the varactor network at a second node, wherein a second output signal of the VCO circuit is generated at the second node;
a first transistor having a first source terminal electrically coupled to the first node and a first gate terminal electrically coupled to the first node; and
a second transistor having a second source terminal electrically coupled to the second node and a second gate terminal electrically coupled to the second node.

11. A VCO oscillator circuit as defined in claim 9, wherein bias voltage generator comprises:
a first resistor to generate the first bias voltage; and
a second resistor to generate the second bias voltage from the first bias voltage;

12. A VCO oscillator circuit as defined in claim 9, wherein the first and second bias voltages are selected to adjust a first capacitance of the first varactor relative to a second capacitance of the second varactor cell.

13. A VCO oscillator circuit as defined in claim 9, wherein the first and second bias voltages are selected to adjust a tuning characteristic of the VCO oscillator circuit.

14. A VCO oscillator circuit as defined in claim 13, wherein the tuning characteristic comprises at least one of a tuning range, a tuning range response or a tuning gain response.

15. A VCO oscillator circuit as defined in claim 9, wherein the first and second varactors are connected to receive a tuning voltage, the tuning voltage configurable to control a capacitance of the varactor network.
